(19) United States
(12) Patent Application Publication
(10) Pub. No.: US 2025/0215747 A1
(43) Pub. Date: Jul. 3, 2025

(54) ROLL-UP SCREEN DEVICE

(71) Applicant: LIXIL Corporation, Tokyo (JP)

(72) Inventor: Hisashi ISHII, Tokyo (JP)

(73) Assignee: LIXIL Corporation, Tokyo (JP)

(21) Appl. No.: 18/849,722

(22) PCT Filed: Sep. 22, 2022
(86) PCT No.: PCT/JP2022/035496

§ 371 Date: Sep. 23, 2024

(30) Foreign Application Priority Data
Mar. 24, 2022 (JP) 2022-048181

(51) Int. Cl. E06B 9/42; E06B 9/24; E06B 9/58; H10F 77/50

(52) U.S. Cl. CPC E06B 9/42; H10F 77/50; E06B 2009/2476; E06B 9/58

(57) ABSTRACT

A roll-up screen device includes a sheet-shaped screen, and a wind-up mechanism that winds the screen. The screen includes a fabric layer, a first encapsulation layer on the fabric layer, a solar cell on the first encapsulation layer, a second encapsulation layer on the solar cell, and a coating layer provided on a surface of the fabric layer facing the first encapsulation layer to restrain an encapsulant constituting the first encapsulation layer from entering the fabric layer.

### CROSS-REFERENCE TO RELATED APPLICATIONS

This application is a national stage application under 35 USC 371 of International Application No. PCT/JP2022/035496, filed Sep. 22, 2022, which claims the priority of Japanese Application No. 2022-048181, filed Mar. 24, 2022. The entire contents of each priority application are incorporated herein by reference.

### FIELD OF THE INVENTION

The present invention relates to a roll-up screen device equipped with solar cells.

### BACKGROUND OF THE INVENTION

Conventionally, a roll-up screen device with solar cells provided in its screen has been known (see Japanese Patent Application Laid-Open Publication No. 2011-179193, for example).

### SUMMARY OF THE INVENTION

In such a roll-up screen device, since solar cells and an encapsulant are arranged on the fabric layer in the screen, the screen tends to be thick and hard, and the screen may not be easily wound up.

The present disclosure has been made in view of such an issue, and a purpose thereof is to provide a technology for improving ease of winding of the screen in a roll-up screen device equipped with solar cells.

To solve the issue above, a roll-up screen device according to one embodiment of the present invention is a roll-up screen device that includes a screen configured in a sheet shape, and a wind-up mechanism that winds the screen. The screen includes a fabric layer, a first encapsulation layer provided on the fabric layer, a solar cell provided on the first encapsulation layer, a second encapsulation layer provided on the solar cell, and a coating layer provided between the fabric layer and the first encapsulation layer to restrain an encapsulant constituting the first encapsulation layer from entering the fabric layer.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a schematic front view of a roll-up screen device according to an embodiment:

FIG. 2 is a schematic sectional view that illustrates a layer structure of a screen.

### DETAILED DESCRIPTION OF THE INVENTION

In the following, the present invention will be described based on a preferred embodiment with reference to the drawings. The configurations described below are intended for illustration for understanding of the present disclosure, and the scope of the present disclosure is defined only by the scope of the claims attached herein. Like reference characters denote like or corresponding constituting elements and members in each drawing, and repetitive description will be omitted as appropriate. Also, the dimensions of a member may be appropriately enlarged or reduced in each drawing in order to facilitate understanding. Further, in each drawing, part of a member less important in describing the embodiment may be omitted.

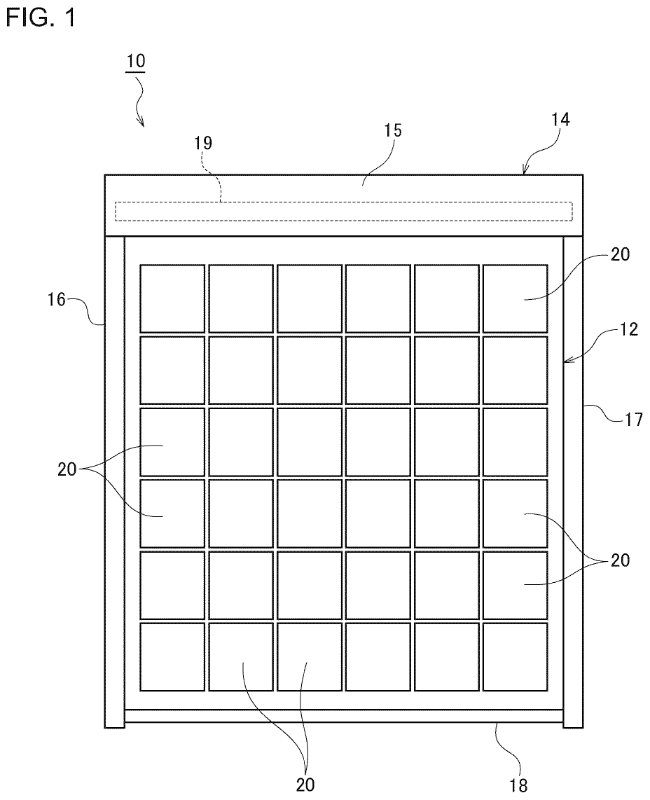

FIG. 1 is a schematic front view of a roll-up screen device 10 according to an embodiment. The roll-up screen device 10 is mounted on an opening in a building and used.

The roll-up screen device 10 includes a screen 12, a holding unit 14 that suspends and holds the screen 12, and a pair of guide rails 16 and 17 that guide the screen 12 lifting and lowering.

The screen 12 is configured as a rectangular sheet-like body having flexibility. The screen 12 is connected, at its upper end in a long side direction, to a wind-up mechanism 19 in the holding unit 14 and is provided, at its lower end, with a bottom rail 18. The bottom rail 18 applies a force in the direction of pulling the screen 12 downward and also applies tension to the screen 12 so as to increase the flatness thereof.

The screen 12 incorporates multiple solar cells 20. In the example shown in FIG. 1, multiple solar cells 20 of square shape in plan view are arranged in a matrix. However, the size, shape, and arrangement method of the solar cells 20 are not particularly limited, and any size, shape, or arrangement can be freely employed. For example, multiple solar cells 20 of rectangular shape in plan view may be arranged along an up or down direction of the screen 12. In general, matrix arrangement is frequently used for crystalline silicon solar cells. The solar cells 20 are configured to use photovoltaic effect and convert optical energy into electricity.

The holding unit 14 includes the wind-up mechanism 19 for winding the screen 12, and a case 15 that houses the wind-up mechanism 19. For the operations of lifting and lowering the screen 12, a known method may be employed, such as a pull cord type or a chain type. Alternatively, an electric motor may be provided in the case 15 so that the screen 12 may be electrically operated.

The guide rails 16 and 17 are arranged respectively at the left and right ends of the screen 12 and are each configured to sandwich an end of the screen 12. Such a configuration can prevent light leakage and heat leakage from the sides of the screen 12, so that the light shielding performance, heat shielding performance, and thermal insulation performance can be improved. Also, the effect of suppressing wrinkling of the screen 12 can be expected.

Also, the screen 12 incorporating the solar cells 20 has a property of wrinkles and an uneven surface being more likely to occur, compared to a fabric shade with no solar cells. By providing the guide rails 16 and 17, wrinkles and an uneven surface of the screen 12 can be reduced. The gap between a guide rail and the roll-up screen may be sealed with mohair or the like.

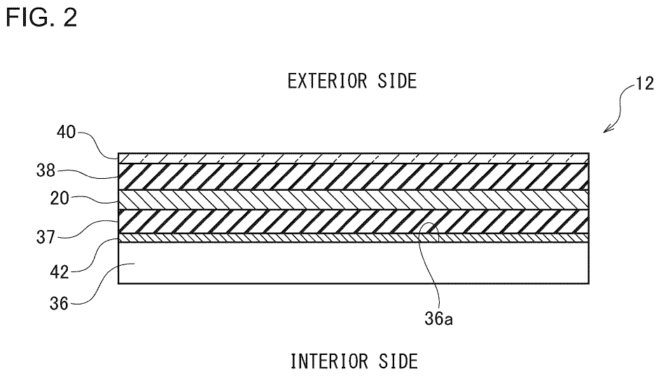

FIG. 2 is a schematic sectional view that illustrates a layer structure of the screen 12. The screen 12 includes a fabric layer 36 disposed on the most interior side, a first encapsulation layer 37 provided on the fabric layer 36, the solar cells 20 provided on the first encapsulation layer 37, a second encapsulation layer 38 provided on the solar cells 20, and a covering layer 40 provided on the second encapsulation layer 38. The covering layer 40 is disposed on the most exterior side. Thus, the solar cells 20 are sandwiched by a pair of encapsulation layers (the first encapsulation layer 37 and the second encapsulation layer 38). The thickness of the screen 12 may be, for example, 0.5 to 2.0 mm.

For the solar cells 20, thin-film silicon may be used; however, the solar cells 20 are not limited to thin-film silicon solar cells and may be organic thin-film solar cells, dye-sensitized solar cells, perovskite solar cells, CIGS solar cells, CIS solar cells, or a tandem structure that contains those solar cells.

The first encapsulation layer 37 is provided to cover the back surface of each solar cell 20. The second encapsulation layer 38 is provided to cover the light-receiving surface of each solar cell 20. As a material of an encapsulation layer, an olefinic elastomer (TPO) can be used. In general, for the second encapsulation layer 38, a material with high transmittance is selected; however, as an ingenious feature in design, the second encapsulation layer 38 may be colored.

The covering layer 40 is provided to cover the second encapsulation layer 38. The covering layer 40 may be formed of a transparent or translucent resin, such as ETFE (Ethylene Tetra Fluoro Ethylene). Alternatively, for the purpose of improving the design, for example, the covering layer 40 may be formed of a colored resin or may have a design pattern printed or embossed thereon.

The fabric layer 36 may be formed of fiber or plastics (synthetic resin), such as polypropylene, polyethylene, and polyester. In order to provide the fabric layer 36 with light shielding properties, the weave may be made denser to reduce a gap between the warp and weft, or a colored opaque resin may be used, for example. Also, the fabric layer may be configured by three-dimensionally intertwining ultra-fine nylon or polyester fiber to randomly provide gaps, allowing light to diffuse and penetrate.

In the present embodiment, on a surface 36a of the fabric layer 36 facing the first encapsulation layer 37, a coating layer 42 is provided. The coating layer 42 restrains an encapsulant constituting the first encapsulation layer 37 from entering the fabric layer. In the manufacturing process of the screen 12, an encapsulant constituting the first encapsulation layer 37 is applied on the surface 36a of the fabric layer 36. At the time, a phenomenon occurs in which the encapsulant enters and penetrates into numerous fine asperities on the surface 36a of the fabric layer 36 and then hardens and increases stiffness. This phenomenon is called the “anchor effect”. The inventor has found, while conducting research and development of roll-up screen devices provided with solar cells, that such an anchor effect increases the stiffness of the fabric layer, which adversely affects the winding of the screen.

The inventor has conducted diligent study to eliminate the anchor effect and found that providing the coating layer 42 on the surface 36a of the fabric layer 36 facing the first encapsulation layer 37 can restrain the encapsulant constituting the first encapsulation layer 37 from entering the fabric layer 36 and hence can prevent the phenomenon where the stiffness of the fabric layer 36 increases. Since the original stiffness of the fabric layer 36 is maintained, hardening of the screen 12 is prevented, so that the ease of winding of the screen 12 can be improved.

The coating layer 42 may be formed of a polyurethane resin or silicone rubber, for example. The thickness of the coating layer 42 may be 1 μm to 10 μm, may be 1 μm to 50 μm, or may be 1 μm to 100 μm, for example. The coating may be performed, for example, by application with a roll coater or by dipping.

Although the type of the fabric layer 36 is not particularly limited, when the fabric layer 36 is formed of polyester, for example, the coating layer 42 may suitably be formed of diluted polyurethane resin or silicone rubber.

The present invention has been described with reference to an embodiment. The embodiment is intended to be illustrative only, and it will be obvious to those skilled in the art that various modifications and changes could be developed within the scope of claims of the present invention and that such modifications and changes also fall within the scope of claims of the present invention. Therefore, the description in the present specification and the drawings should be regarded as illustrative rather than limitative.

What is claimed is:

1. A roll-up screen device comprising:
a screen configured in a sheet shape, and
a wind-up mechanism that winds the screen,
wherein the screen comprises:
a fabric layer;
a first encapsulation layer provided on the fabric layer;
a solar cell provided on the first encapsulation layer;
a second encapsulation layer provided on the solar cell; and
a coating layer provided between the fabric layer and the first encapsulation layer to restrain an encapsulant constituting the first encapsulation layer from entering the fabric layer.

2. The roll-up screen device of claim 1, wherein the coating layer is formed of a polyurethane resin or silicone rubber.

3. The roll-up screen device of claim 1, wherein the coating layer has a thickness of 1 μm to 100 μm.

4. The roll-up screen device of claim 2, wherein the coating layer has a thickness of 1 μm to 100 μm.
